(19) United States
(12) Patent Application Publication
(10) Pub. No.: US 2019/0102005 A1
(43) Pub. Date: Apr. 4, 2019

(54) DISPLAY DEVICE WITH TOUCH SENSOR AND METHOD OF MANUFACTURING DISPLAY DEVICE WITH TOUCH SENSOR

(71) Applicant: Japan Display Inc., Minato-ku (JP)

(72) Inventor: Yuko MATSUMOTO, Minato-ku (JP)

(73) Assignee: Japan Display Inc., Minato-ku (JP)

(21) Appl. No.: 16/135,651

(22) Filed: Sep. 19, 2018

(30) Foreign Application Priority Data
Oct. 3, 2017 (JP) 2017-193745

(51) Int. Cl. G06F 3/044; H01L 27/32; G06F 3/041; H01L 51/52; H01L 51/56

(52) U.S. Cl. CPC G06F 3/044; H01L 27/323; G06F 3/0412; H01L 27/3246; H01L 51/5206; H01L 51/56; H01L 51/5225; H01L 27/3211; H01L 51/5246

(57) ABSTRACT

A display device with a touch sensor according to an embodiment of the invention includes: a substrate; a terminal; a light emitting element; a sealing film including a first insulating film; a plurality of first touch electrodes, two of the first touch electrodes that are adjacent to each other in a first direction being connected to each other via a first connection line; a plurality of second touch electrodes, two of the second touch electrodes that are adjacent to each other in a second direction being connected to each other via a second connection line; an interlayer insulating film which is interposed between the first connection line and the second connection line, and has an end face continuous to an end face of the first insulating film; and a leader wiring which is disposed over the end face of the first insulating film and the end face of the interlayer insulating film, and connects the first touch electrode or the second touch electrode to the terminal.

### CROSS-REFERENCE TO RELATED APPLICATION

The present application claims priority from Japanese Application JP 2017-193745 filed on Oct. 3, 2017, the content of which is hereby incorporated by reference into this application.

### BACKGROUND OF THE INVENTION

### 1. Field of the Invention

One or more embodiments of the present invention relate to a display device with touch sensor, and a manufacturing method thereof.

### 2. Description of the Related Art

Japanese Patent Application Laid-Open No. 2015-050245A discloses a display device which includes an organic electroluminescence element disposed over a substrate, and an inorganic insulating film which covers this organic electroluminescence element. Further, over the inorganic insulating film, a touch sensor which is built in the display device is given. The touch sensor is configured that first electrodes extending in an X-direction where main body parts adjacent to each other are connected to each other via connection parts and second electrodes extending in a Y-direction where main body parts adjacent to each other are connected to each other via connection parts are opposed to each other, with an interposition of an interlayer insulating layer. The second electrodes extending in the Y-direction are connected to exposed terminals from the upper surface side of the substrate.

### SUMMARY OF THE INVENTION

As to the conventional configuration as described above, further improvement of the manufacturing efficiency was the issue. That is, the conventional configuration as described above requires a process to remove the inorganic insulating layer formed on the upper surface of terminals and a process to remove the interlayer inorganic insulating layer formed on the upper surfaces of terminals. Therefore, the improvement of the manufacturing efficiency was the issue.

The object of an embodiment of the present invention is to improve the manufacturing efficiency of a display device with touch sensor.

A display device with a touch sensor according to an embodiment of the present invention includes: a substrate; a first terminal which is on an upper surface side of the substrate; a light emitting element which is on the upper surface side of the substrate; a sealing film having a first inorganic insulating film, which covers the light emitting element, a plurality of first touch electrodes which are arranged two dimensionally over the sealing film, two of the first touch electrodes that are adjacent to each other in a first direction being connected to each other via a first connection line; a plurality of second touch electrodes which are arranged two dimensionally over the sealing film, two of the second touch electrodes that are adjacent to each other in a second direction which intersects the first direction being connected to each other via a second connection line which intersects the first connection line in a plan view; an interlayer insulating film which is between the first connection line and the second connection line, and has an end face continuous to an end face of the first inorganic insulating film; and a leader wiring which is over the end portion of the first inorganic insulating film and the end portion of the interlayer insulating film, and connects the first touch electrode or the second touch electrode to the first terminal.

### BRIEF DESCRIPTION OF THE DRAWINGS

FIG. 1 is a schematic plan view of display device with touch sensor according to a present embodiment.

FIG. 2 is a magnified plan view of a region inside the dashed line in FIG. 1.

FIG. 3 is a schematic cross sectional view of a cross section taken along line in FIG. 1.

FIG. 4 is a magnified cross sectional view of a border part between a display region and a peripheral region in FIG. 3.

FIG. 5 is a schematic cross sectional view which explains a manufacturing method of the display device with touch sensor according to the present embodiment.

FIG. 6 is a schematic cross sectional view which explains a manufacturing method of the display device with touch sensor according to the present embodiment.

FIG. 7 is a schematic cross sectional view which explains a manufacturing method of the display device with touch sensor according to the present embodiment.

FIG. 8 is a schematic cross sectional view which explains a manufacturing method of the display device with touch sensor according to the present embodiment.

FIG. 9 is a schematic cross sectional view which explains a manufacturing method of the display device with touch sensor according to the present embodiment.

FIG. 10 is a schematic cross sectional view which explains a manufacturing method of the display device with touch sensor according to the present embodiment.

FIG. 11 is a schematic cross sectional view which explains a manufacturing method of the display device with touch sensor according to the present embodiment.

### DETAILED DESCRIPTION OF THE INVENTION

Below, each of the one or more embodiments of the present invention is explained with reference to the accompanying drawings. Note that the one or more disclosed embodiments are merely examples, and an appropriate variation which a person skilled in the art can easily arrive at without departing from the spirit of the present invention is naturally included in the scope of the present invention. Further, while the width, thickness, shape, and the like of each part in the drawings may be illustrated schematically as compared with the actual embodiments in order to clarify the explanation, these are merely examples, and an interpretation of the present invention should not be limited thereto. Furthermore, in the specification and the respective drawings, the same reference symbols may be applied to elements similar to those which have already been illustrated in another drawing, and a detailed description of such elements may be omitted as appropriate.

Further, in the detailed description of the one or more embodiments of the present invention, when a positional relationship between one component and another component is defined, the words “on” and “under” are not used only in a case where the other component is positioned directly on or directly under the one component, but those words are also used in a case where still another component is interposed between the one component and the other component, unless otherwise stated.

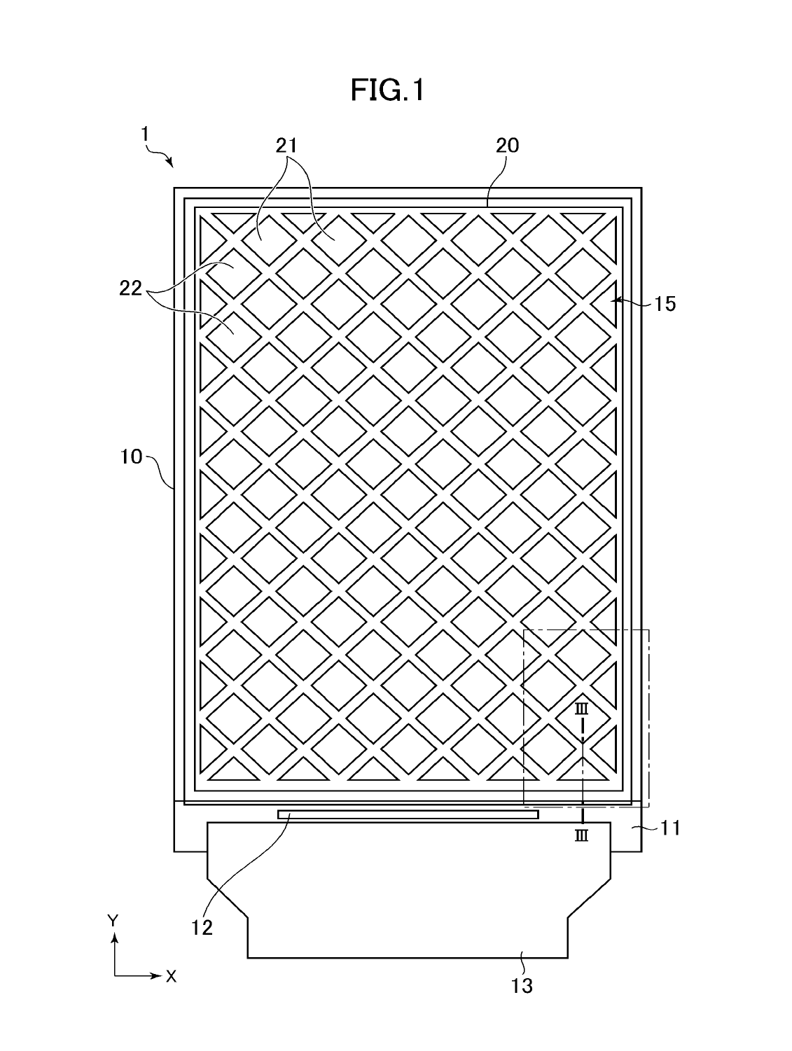

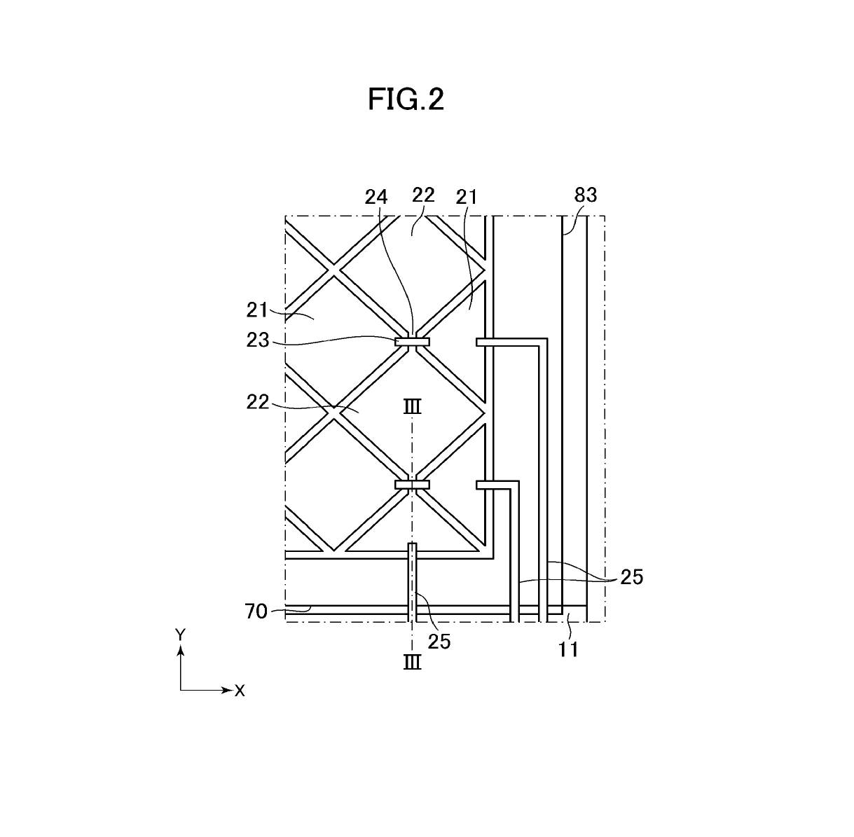

FIG. 1 is a plan view of a display device with touch sensor according to the one or more embodiments (hereinafter referred to simply as a display device). FIG. 2 is a magnified view of a region inside the dashed line shown in FIG. 1. As an example of the display device, an organic EL display device is mentioned. A display device 1 forms a full color pixel by combining unit pixels of a plurality of colors (subpixels) which are constituted by red, green, and blue, for example, and displays a full color image.

The display device 1 has a display panel 10, and a touch sensor 20 formed over a display region 15 of the display panel 10. A peripheral region (a frame region) 11 is formed outside the display region 15 of the display panel 10. On the peripheral region 11, an integrated circuit chip 12 for driving pixels is mounted, and to the peripheral region 11, an FPC (a flexible printed circuit) 13 for an electric connection to the outside is connected. In the explanation below, it is provided that a direction along the side to which FPC 13 of the peripheral region 11 is connected is the X direction, and a direction which is orthogonal to the X direction is the Y direction.

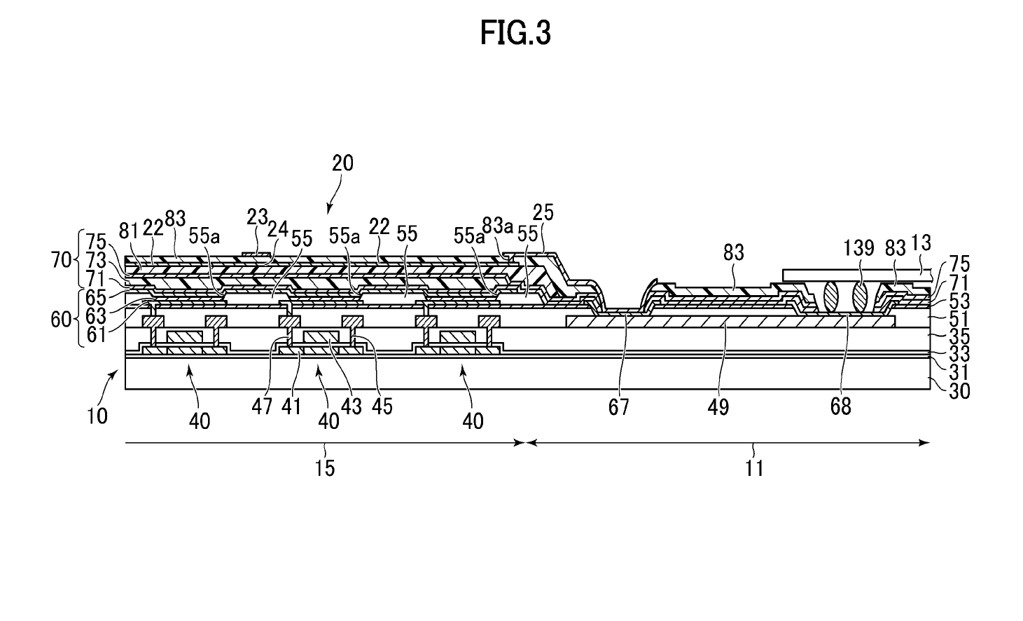

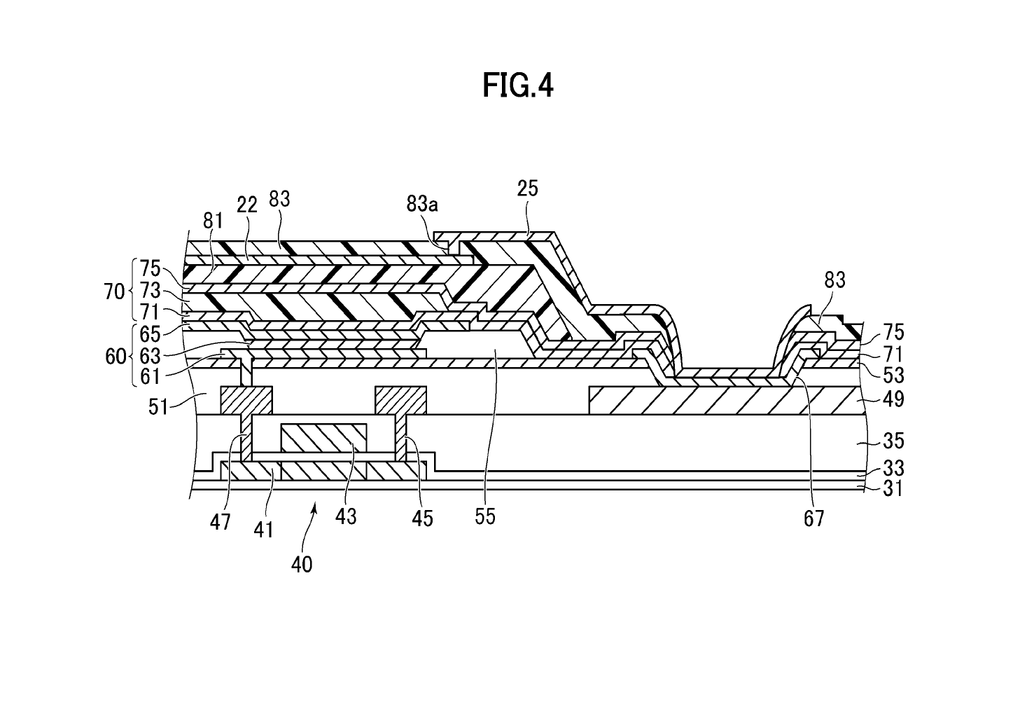

FIG. 3 is a cross sectional view of a cross section along line shown in FIG. 1. FIG. 4 is a magnified view of a border part between the display region 15 and the peripheral region 11 in FIG. 3. In those figures, in order to make the cross sectional structure easy to see, hatching of some layers such as a substrate 30, a planarizing film 51, a pixel separation film 55, and the like is omitted. In the description below, it is provided that the stacking direction is the upper direction.

The substrate 30 is formed, for example, of glass, or flexible resin such as polyimide. The substrate 30 is covered by an undercoat layer 31. On the undercoat layer 31, a semiconductor layer 41 is formed, and the semiconductor layer 41 is covered by the gate insulating film 33. On the gate insulating film 33, a gate electrode 43 is formed, and the gate electrode 43 is covered by the passivation film 35. The drain electrode and the source electrode 47 penetrate the gate insulating film 33 and the passivation film 35, and are connected to the semiconductor layer 41. The semiconductor layer 41, the gate electrode 43, the drain electrode 45, and the source electrode 47 constitute a thin film transistor 40. The thin film transistor 40 is provided so as to correspond to each of the plurality of unit pixels. The undercoat layer 31, the gate insulating film 33, and the passivation film 35 are formed of an inorganic insulating material such as SiO₂, SiN, and SiON.

On the passivation film 35, in addition to the drain electrode 45 and the source electrode 47, a wiring 49 is formed in the peripheral region 11. The illustrated wiring 49 is a wiring for electrically connecting the touch sensor 20 and the FPC 13. The drain electrode 45, the source electrode 47, and the wiring 49 are covered by the planarizing film 51, and the planarizing film 51 is covered by an inorganic insulating film 53. The drain electrode 45, the source electrode 47, and the wiring 49 are formed of a conductive material containing Al, Ag, Cu, Ni, Ti, Mo, or the like, for example. The planarizing film 51 is formed of an organic insulating film such as acrylic resin, and has a flat upper surface. The inorganic insulating film 53 is formed of an inorganic insulating material such as SiO₂, SiN, and SiON.

On the inorganic insulating film 53, a pixel electrode 61 (e.g., an anode) is formed. The pixel electrode 61 penetrates the planarizing film 51 and the inorganic insulating film 53, and is connected to the source electrode 47. The pixel electrode 61 is provided so as to correspond to each of the plurality of unit pixels. The pixel electrode 61 is formed as a reflection electrode. Further, in the peripheral region 11, a first terminal 67 and a second terminal 68 which are not covered by the inorganic insulating film 53 or the like are formed on the upper surface side of the substrate 30, penetrate the planarizing film 51 and the inorganic insulating film 53 and are respectively connected to the both of the edges of the wiring 49. The second terminal 68 is disposed at a position which is separated from the display region 15 more than the first terminal 67 is. That is, the second terminal 68 is disposed at a position which is separated from a light emitting element 60 to be described later more than the first terminal 67 is.

The pixel electrode 61, the first terminal 67, and the second terminal 68 are formed to contain a conductive material containing Al, Ag, Cu, Ni, Ti, Mo, or the like, for example. Further, the first terminal and the second terminal 68 have many chances to be exposed to the atmosphere during the process, and therefore may contain a material whose surface is hardly oxidized, that is, indium based oxide such as ITO and IZO. In other words, they may have a two layer structure of a conductive material containing Al, Ag, Cu, Ni, Ti, Mo, or the like, and indium based oxide whose surface is hardly oxidized. In the case where the first terminal 67 and the second terminal 68 contain indium based oxide on their surface side, when removing a first inorganic insulating film 71, a second inorganic insulating film 75, an interlayer insulating film 83, and the like to be described later by etching, the indium based oxide is preferable since its selection ratio with respect to etching liquid is small and the shapes of the first terminal 67 and the second terminal can be retained. Further, in the case where the display device 1 is of the bottom emission type, the pixel electrode 61 needs to be formed as a transmission electrode, and in this case as well the indium based oxide as above can be used.

Around the pixel electrode 61, the pixel separation film 55 is disposed. The pixel separation film 55 is referred to also as a rib or a bank. On the pixel separation film 55, an opening 55a at the bottom of which the pixel electrode 61 is exposed is formed. The inner periphery portion of the pixel separation film 55 which forms the opening 55a is on the periphery part of the pixel electrode 61, and has a tapered form which extends outward, as it extends upward. Note that the pixel separation film 55 is formed in the display region and in the vicinity of the border between the peripheral region 11 and the display region 15. The pixel separation film 55 is formed of an organic insulating material such as acrylic resin.

On the pixel electrode 61 which is exposed at the bottom of the opening 55a of the pixel separation film 55, light emitting layers 63 are individually formed to be separated from one another. The light emitting layers 63 emit lights in a plurality of colors composed of, for example, red, green, and blue, in correspondence with each of the plurality of unit pixels. Together with the light emitting layers 63, at least one of a hole transport layer, a hole injection layer, an electron transport layer, and an electron injection layer may be formed. The light emitting layers 63 are individually formed by evaporation using a mask. The light emitting layers 63 may be formed by evaporation as a uniform film which extends all over the display region 15. In such a case, the light emitting layers 63 emit light in a single color (e.g., white), and each of components of the plurality of colors composed of, for example, red, green, and blue is extracted by a color filter or a color conversion layer. Note that the light emitting layers 63 don't have to be formed by evaporation necessarily, and they may be formed by application as well.

The light emitting layers 63 and the pixel separation film 55 are covered by an opposition electrode 65 (e.g., a cathode). The opposition electrode 65 is formed as a uniform film which extends all over the display region 15. The light emitting element 60 is constituted by the light emitting layer 63, the pixel electrode 61, and the opposition electrode (the pixel electrode 61 and the opposition electrode hold the light emitting layer 63 between them), and the light emitting layer 63 emits light by a current which runs between the pixel electrode 61 and the opposition electrode 65. The opposition electrode 65 is formed of a transparent conductive material such as ITO, or a metal film such as an MgAg film. In the case where the display device 1 is of the top emission type, the opposition electrode 65 needs to be formed as a transmission electrode, and if a metal film is used, the film thickness needs to be small so that light can transmit through the film.

The pixel separation film 55 and the opposition electrode 65 are covered by a sealing film (a passivation film) 70 to thereby be sealed and be shut off from moisture. The sealing film 70 has a three layer lamination structure which includes, for example, the first inorganic insulating film 71, an organic insulating film 73, and the second inorganic insulating film 75 from the bottom in this order. The first inorganic insulating film 71 and the second inorganic insulating film 75 are formed of an inorganic insulating material such as SiO₂, SiN, and SiON. The organic insulating film 73 is formed of an organic insulating material such as acrylic resin, and planarize the upper surface of the sealing film 70.

Here, the end face of the first inorganic insulating film 71 and the end face of the second inorganic insulating film 75 are configured to be continuous to each other. This is formed by etching the end face of the first inorganic insulating film 71 and the end face of the second inorganic insulating film 75 at the same time, when exposing the contact region of the first terminal 67 which is connected to the leader wiring 25 by an etching process to be described later. The end face of the first inorganic insulating film 71 is disposed between the light emitting element and the first terminal 67. Note that the angle between this end face of the first inorganic insulating film 71 and the substrate 30 is preferably 40 degrees or less. According to a configuration like this, one can suppress breakage of a leader wiring 25 to be described later.

The display device 1 has a touch sensor 20 on the sealing film 70. Specifically, a protective insulating film 81 is formed on the sealing film 70, and on the protective sealing film 81 a plurality of first touch electrodes 21 and a plurality of second touch electrodes 22 which are arranged two dimensionally are formed. On the first touch electrodes 21 and the second touch electrodes 22 the interlayer insulating film 83 is formed. The first touch electrode 21 and the second touch electrode 22 constitute a drive electrode and a detection electrode of a capacitive touch sensor. The protective insulating film 81 and the interlayer insulating film 83 are formed of an organic insulating material such as acrylic resin. Note that the protective insulating film 81 can be omitted, and in that case, it is configured that the first touch electrode 21 and the second touch electrode 22 are formed on the sealing film 70.

As illustrated in FIG. 1 and FIG. 2, the first touch electrodes 21 and the second touch electrodes 22 are respectively formed in a rectangular shape where the X direction (first direction) and the Y direction (second direction) which intersects (e.g., is orthogonal to) the X direction are the diagonal directions, that is, what is called a rhombus shape (diamond shape).

In the present embodiment, the first touch electrode 21 and the second touch electrode 22 have a lamination structure including a first layer containing a material such as Ag and MoW which is in ohmic contact with an indium based material, and a second layer which is provided on the first layer and contains indium based oxide such as ITO, IZO, and IGZO. By providing the second layer containing indium based oxide on the surface sides of the first touch electrode 21 and the second touch electrode 22, during a process of forming the opening 83a on the interlayer insulating film 83 to be described later, the shapes of the first touch electrode 21 and the second touch electrode 22 can be retained, which is preferable. That is, the indium based oxide has a selection ratio which is small with respect to the etching liquid used when etching an inorganic insulating material such as SiO₂, SiN, and SiON, and therefore the shapes of the first touch electrode 21 and the second touch electrode 22 can be retained.

As illustrated in FIG. 1 and FIG. 2, the plurality of first touch electrodes 21 are arranged two dimensionally in series in the X direction and in the Y direction respectively. Among those first touch electrodes 21, any two of the first touch electrodes 21 that are adjacent to each other in the X direction are connected to each other by a first connection line 23, and any two of the first touch electrodes 21 that are adjacent to each other in the Y direction are not connected to each other. That is, the plurality of first touch electrodes 21 form a plurality of electrode rows which extend in the X direction as any two of the first touch electrodes 21 that are adjacent to each other in the X direction are connected to one another by the first connection line 23, and the respective electrode rows are electrically separated from each other in the Y direction.

Also, the plurality of second touch electrodes 22 are arranged two dimensionally in series in the X direction and in the Y direction respectively. Among those second touch electrodes 22, any two of the second touch electrodes 22 that are adjacent to each other in the Y direction are connected to each other by a second connection line 24 which intersects the first connection line 23 in a plan view, and any two of the second touch electrodes 22 that are adjacent to each other in the X direction are not connected to each other. That is, the plurality of second touch electrodes 22 form a plurality of electrode rows which extend in the Y direction as any two of the second touch electrodes 22 that are adjacent to each other in the Y direction are connected to each other by the second connection line 24, and the respective electrode rows are electrically separated from one another in the X direction.

Each of the second touch electrodes 22 is arranged so as to be surrounded by the first touch electrodes 21 in a plan view. For example, each of the second touch electrodes 22 is arranged between the first touch electrodes 21 that are adjacent to each other in a direction which intersects both of the X direction and the Y direction (e.g., the positive 45 degree direction or the negative 45 degree direction), and is surrounded by four first touch electrodes 21. The first touch electrodes 21 and the second touch electrodes 22 are electrically separated from each other by putting a space between them so that they do not contact with each other.

In the present embodiment, the plurality of first touch electrodes 21 and the plurality of second touch electrodes 22 are disposed in the same layer between the sealing film 70 and the interlayer insulating film 83, but the configuration is not limited to this, and they may be disposed in different layers. That is, it may be configured that either of the first touch electrodes 21 and the second touch electrodes 22 is disposed under the interlayer insulating film 83, and the other is disposed on the interlayer insulating film 83. Further, both of the first touch electrodes 21 and the second touch electrodes 22 may be disposed on the interlayer insulating film 83.

As illustrated in FIG. 2 and FIG. 3, the first connection line 23 and the second connection line 24 intersect each other in a plan view. Between the first connection line 23 and the second connection line 24 which intersect each other in a plan view, the interlayer insulating film 83 is interposed, and the two lines are electrically separated from each other.

In the present embodiment, the first connection line 23 is a so-called bridge wiring, which is disposed on the interlayer insulating film 83. The first connection line 23 is connected to the first touch electrode 21 via a through hole formed on the interlayer insulating film 83. Whereas, the second connection line is formed continuously to the second touch electrode under the interlayer insulating film 83. The first connection line 23 is formed of a conductive material containing, for example, Al, Ag, Cu, Ni, Ti, Mo, and the like. The first connection line 23 may have a three layer structure of Ti, Al, and Ti, and may have a three layer structure of Mo, Al, and Mo, for example. By configuring the first connection line 23 to be in such a lamination structure, the resistance of the first connection line 23 can be lowered, and an increase of a time constant of detection in the touch sensor 20 can be suppressed. In the present embodiment, the second connection line 24 has a lamination structure including a first layer containing a material such as Ag and MoW which is in ohmic contact with an indium based material, and a second layer which is provided on the first layer and contains indium based oxide such as ITO, IZO, and IGZO. As such, by configuring the second connection line 24 to have a lamination structure similar to those of the first touch electrode 21 and the second touch electrode 22, in the step of forming the first touch electrode 21 and the second touch electrode 22 as described above, the second connection line 24 can be formed at the same time when forming the first touch electrode 21 and the second touch electrode 22.

Note that the present disclosure is not limited to the configuration as described above, and it may be configured that the second connection line 24 is disposed on the interlayer insulating film 83 as a bridge wiring, and the first connection line 23 is formed continuously to the first touch electrode 21 under the interlayer insulating film 83. Further, an intersection part where the first connection line 23 as a bridge wiring intersects the second connection line 24, and an intersection part where the second connection line 24 as a bridge wiring intersects the first connection line 23 may coexist.

Here, the end face of the interlayer insulating film 83 is configured to be continuous to the end face of the first inorganic insulating film 71 and the end face of the second inorganic insulating film 75 as described above. This is formed by etching the end face of the first inorganic insulating film 71, the end face of the second inorganic insulating film 75, and the interlayer insulating film 83 at the same time, when exposing the contact region of the first terminal 67 to be connected to the leader wiring 25 by an etching process to be described later. According to a configuration like this, it is no longer necessary to go through a plurality of etching processes for exposing the upper surface of the first terminal 67 each time the first inorganic insulating film 71, the second inorganic insulating film 75, and the interlayer insulating film are formed, and it becomes possible to expose the upper surface of the first terminal 67 out of the first inorganic insulating film 71, the second inorganic insulating film 75, and the interlayer insulating film in a single etching process. The end face of the interlayer insulating film 83, the end face of the first inorganic insulating film 71, and the end face of the second inorganic insulating film 75 are arranged between the first terminal 67 and the light emitting element 60 in a plan view.

As shown in FIG. 2 to FIG. 4, the touch sensor 20 has a plurality of leader wirings 25 drawn out from the periphery part of the display region 15 to the peripheral region 11. The leader wiring 25 is formed at the same time as the first connection line 23 on the interlayer insulating film 83. The leader wiring 25 may have a three layer structure of Ti, Al, and Ti, and may have a three layer structure of Mo, Al, and Mo, for example. By configuring the leader wiring 25 to have such a lamination structure, the resistance of the leader wiring 25 can be lowered, and an increase of a time constant of detection in the touch sensor 20 can be suppressed.

The respective leader wirings 25 are connected to the first touch electrode 21 or the second touch electrode 22 via the opening 83a formed on the interlayer insulating film 83, are formed over the end faces of the first inorganic insulating film 71, the second inorganic insulating film 75, and the interlayer insulating film 83, and are connected to the upper surface of the first terminal 67 exposed by the etching process as described above. The leader wirings 25 are connected to the wiring 49 arranged below the light emitting element 60 via the first terminal 67.

Note that the formation of the opening 83a may be performed at the same time as the etching process for exposing the upper surface of the first terminal 67 as described above. At that time, on the first terminal 67, the three layers, namely, the first inorganic insulating film 71, the second inorganic insulating film 75, and the interlayer insulating film 83, are formed. Meanwhile, on the first touch electrode 21 and the second touch electrode 22, only the interlayer insulating film 83 is formed. Therefore, the etching liquid possibly reaches the first touch electrode 21 and the second touch electrode 22 before etching the three layers, namely, the first inorganic insulating film 71, the second inorganic insulating film 75, and the interlayer insulating film 83. However, as described above, in the present embodiment, the first touch electrode 21 and the second touch electrode 22 have, on their surface sides, the structure including the second layer containing indium based oxide such as ITO, IZO, and IGZO. According to the existence of the second layer which has a small selection ratio with respect to the etching liquid, the shapes of the first touch electrode 21 and the second touch electrode 22 can be retained.

Whereas, as illustrated in FIG. 3, the FPC 13 is connected to the second terminal 68 disposed at a position which is separated from the display region 15 more than the first terminal 67 is, via an anisotropic conductive member 139. Further, in the peripheral region 11 an unillustrated terminal (a third terminal) which is electrically connected to the light emitting component 60 is provided, and to this unillustrated terminal the FPC 13 is connected via the anisotropic conductive member 139. This unillustrated terminal is electrically connected to the light emitting element 60 via the thin film transistor 40, the integrated circuit chip 12, and the like, for example.

Further, in the present embodiment, the FPC 13 is connected to both of the second terminal 68 electrically connected to the touch sensor 20 and the unillustrated terminal (the third terminal) electrically connected to the light emitting element 60. Therefore, it is possible to supply a signal to both of the touch sensor 20 and the light emitting element 60 from the outside by this one piece of the FPC 13.

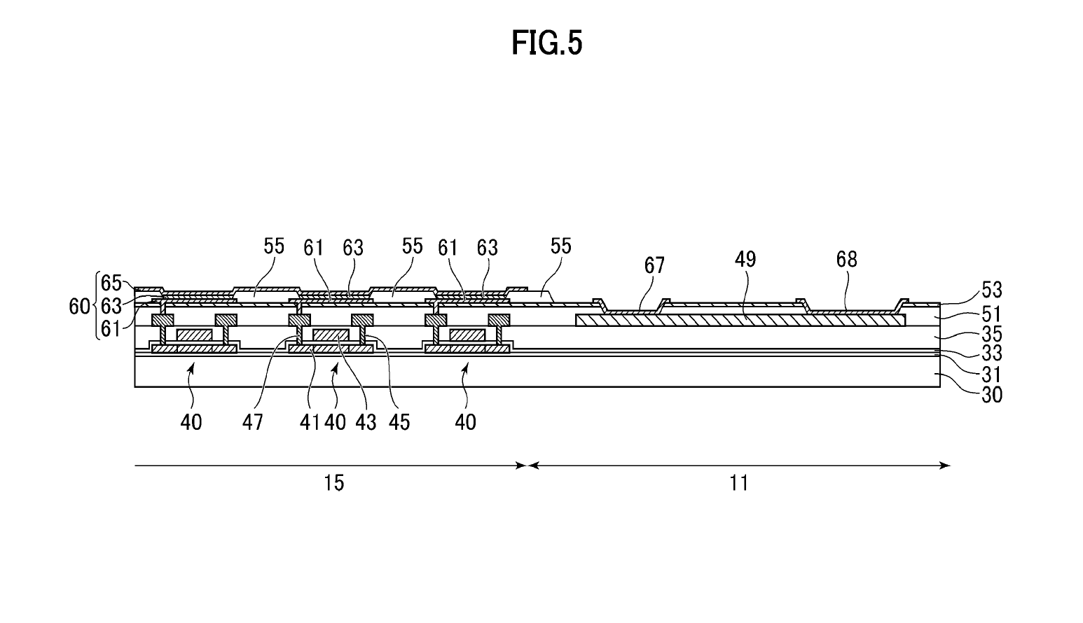

Below, with reference to FIG. 5 to FIG. 10, an exemplary manufacturing process of the display device with touch sensor according to the present embodiment is described.

FIG. 5 illustrates the finished state of the light emitting element 60. In the peripheral region 11, the first terminal 67 and the second terminal 68 are provided. Note that the cross section illustrated in FIG. 5 illustrates the state where the touch sensor 20 is connected to the wiring 49, the first terminal 67, and the second terminal 68. However, at a different position, the opposition electrode 65 of the light emitting element 60 is connected to the wiring 49, the first terminal 67, and the second terminal 68.

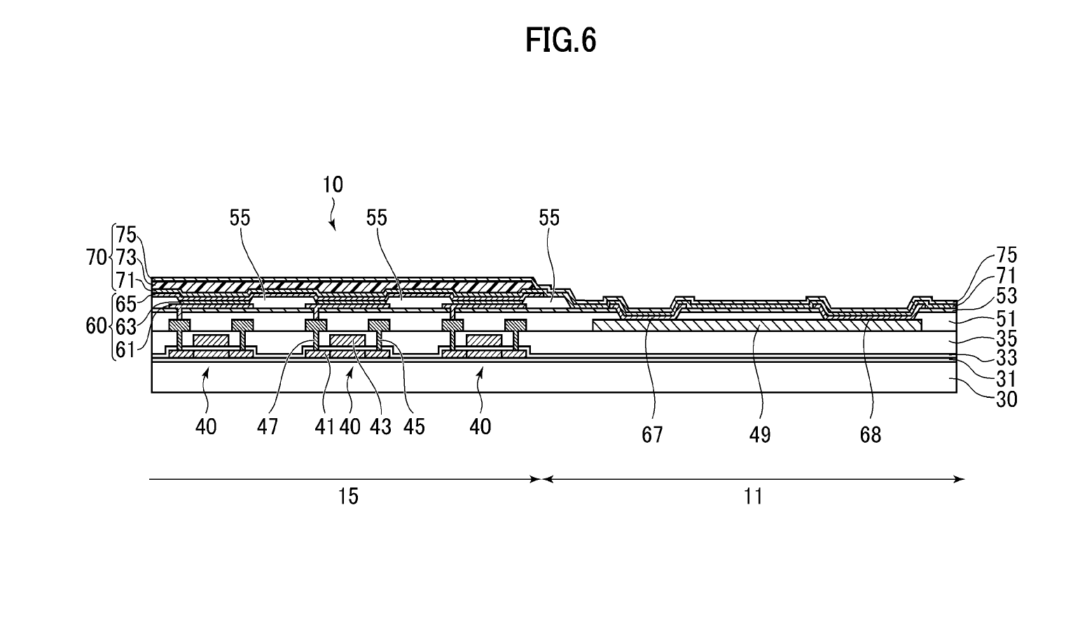

FIG. 6 illustrates a process to form the sealing film 70. Here, the organic insulating film 73 is formed in the display region 15, but is not formed in the peripheral region 11. The organic insulating film 73 is sealed since the first inorganic insulating film 71 and the second inorganic insulating film 75 contact each other outside the outer periphery of the organic insulating film 73. Therefore, the peripheral region 11 is covered by the two layers, namely, the first inorganic insulating film 71 and the second inorganic insulating film 75. The first inorganic insulating film and the second inorganic insulating film 75 are formed for example by the CVD (Chemical Vapor Deposition) method, and the organic insulating film 73 is formed for example by the inkjet method.

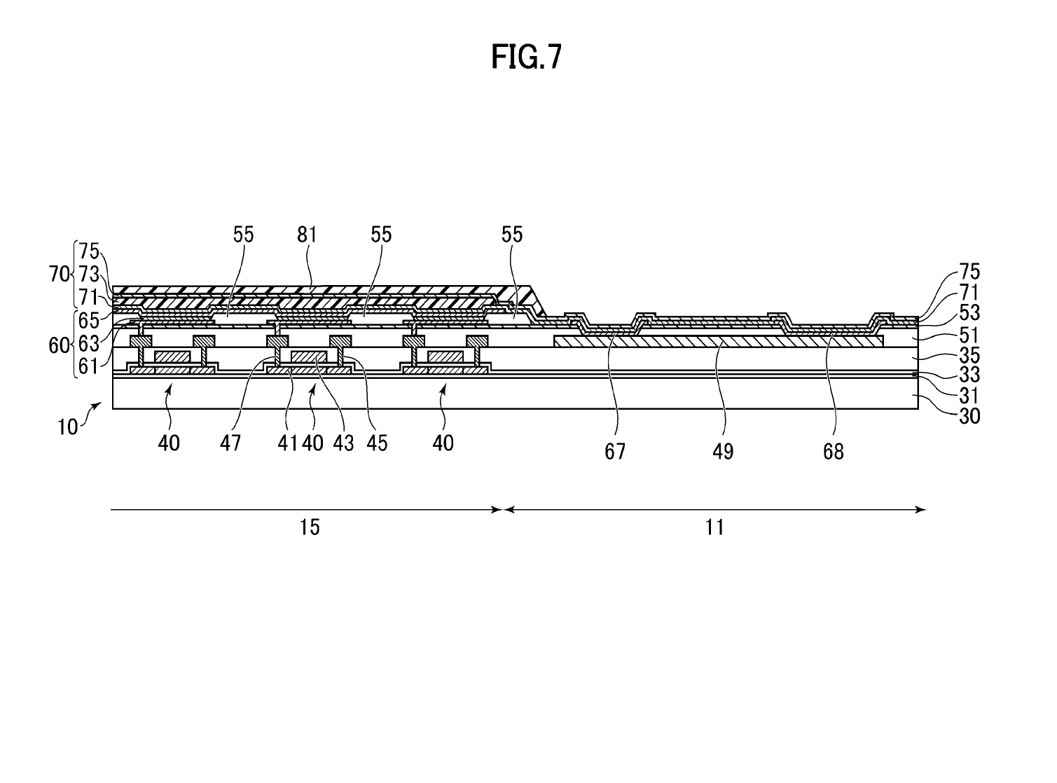

FIG. 7 illustrates a process to form the protective insulating film 81. Here, the protective insulating film 81 is formed in the display region 15, but is not formed in the peripheral region 11. Specifically, the outer periphery of the protective insulating film 81 is located outside the outer periphery of the pixel separation film 55. The protective insulating film 81 is formed of an organic insulating material, and improves the degree of flatness in the display region 15. Note that this process to form the protective insulating film 81 may be skipped.

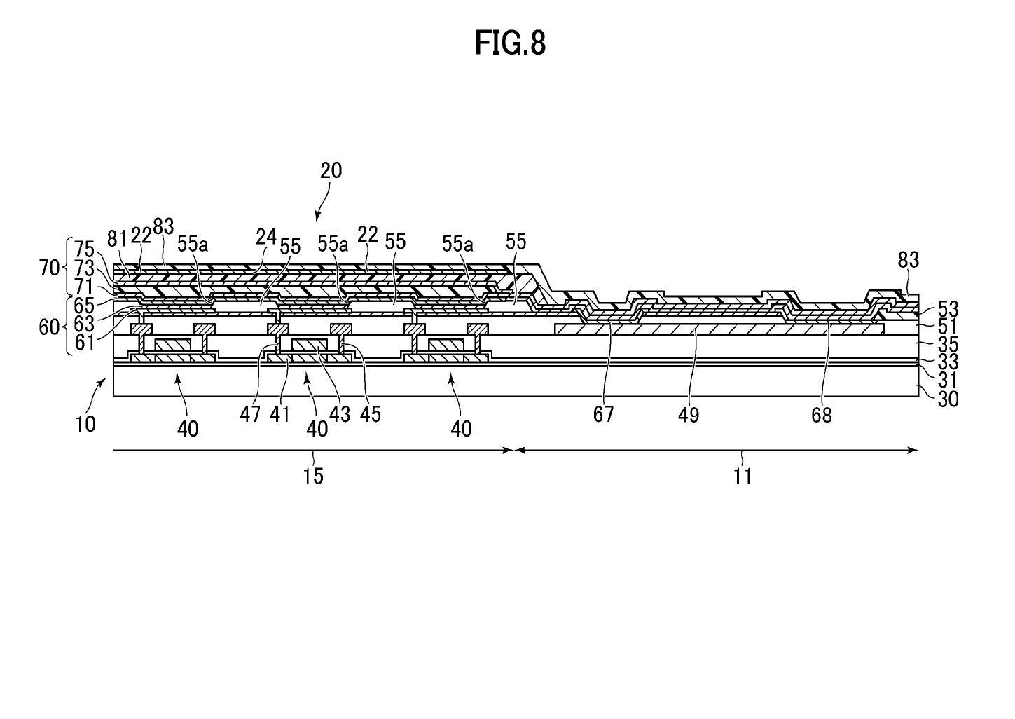

FIG. 8 illustrates a process to form the touch sensor 20. Firstly, on the protective insulating film (on the sealing film 70 instead, in the case where the protective insulating film 81 is not formed), the first touch electrode 21, the second touch electrode 22, and the second connection line 24 are formed. At that time, the first touch electrode 21, the second touch electrode 22, and the second connection line 24 are formed to have a lamination structure including a first layer containing a material such as Ag and MoW which is in ohmic contact with an indium based material, and a second layer which is provided on the first layer and contains indium based oxide such as ITO, IZO, and IGZO. By providing the second layer containing indium based oxide on the surface sides of the first touch electrode 21 and the second touch electrode 22, during the process to form the opening 83a on the interlayer insulating film 83 to be described later, the shapes of the first touch electrode 21 and the second touch electrode 22 can be retained, which is preferable. That is, the indium based oxide has a small selection ratio with respect to the etching liquid which is used when etching an inorganic insulating material such as SiO₂, SiN, and SiON, and therefore the shapes of the first touch electrode 21 and the second touch electrode 22 can be retained. The first touch electrode 21, the second touch electrode 22, and the second connection line 24 are formed by pattern formation including the photolithography process and the wet etching process.

Thereafter, the interlayer insulating film 83 is formed for example by the mask CVD method or the like. The interlayer insulating film 83 is formed so as to cover the upper surfaces of the first touch electrode 21, the second touch electrode 22, and the second connection line 24 to the upper surface of the first terminal 67. In the present embodiment, the interlayer insulating film 83 is formed of an inorganic insulating material such as SiO₂, SiN, and SiON just as the first inorganic insulating film 71 and the second inorganic insulating film 75. By choosing the material of the interlayer insulating film 83 to be the same inorganic insulating material as those for the first inorganic insulating film 71 and the second inorganic insulating film 75, it becomes possible to etch the interlayer insulating film 83, the first inorganic insulating film 71, and the second inorganic insulating film 75 all together.

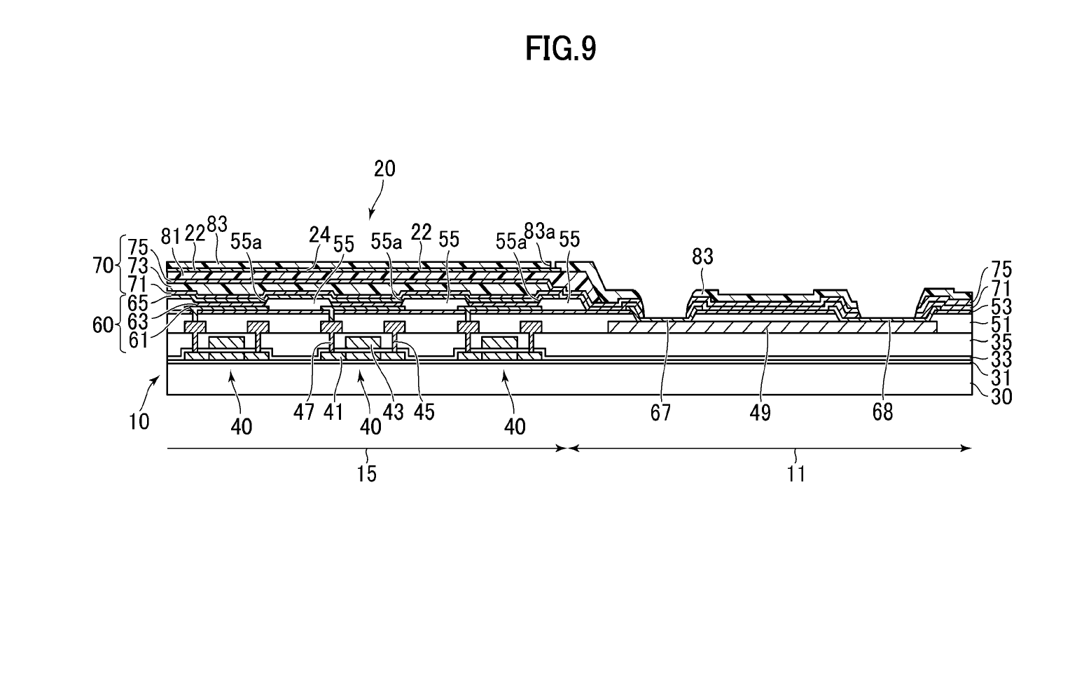

FIG. 9 illustrates an etching process to expose the first terminal 67. In a single etching process, the first inorganic insulating film 71, the second inorganic insulating film 75, and the interlayer insulating film which are formed on the contact region of the first terminal 67 are removed. According to a manufacturing method like this, it is no longer necessary to have a plurality of etching processes for exposing the upper surface of the first terminal 67 each time the first inorganic insulating film 71, the second inorganic insulating film 75, and the interlayer insulating film 83 are formed, and it becomes possible to expose the upper surface of the first terminal 67 out of the first inorganic insulating film 71, the second inorganic insulating film 75, and the interlayer insulating film 83 in a single process.

In the case where the manufacturing method like this has been executed, as illustrated in FIG. 9, the end face of the interlayer insulating film 83 is configured to be continuous to the end face of the first inorganic insulating film 71 and the end face of the second inorganic insulating film 75.

Further, in this etching process, the opening 83a which exposes the first touch electrode 21 or the second touch electrode 22 may be formed at the same time when the contact region of the first terminal 67 is exposed. As described above with reference to FIG. 8, the first touch electrode 21, the second touch electrode 22, and the second connection line 24 are formed to have a lamination structure including a first layer containing a material such as Ag and MoW which is in ohmic contact with an indium based material, and a second layer which is provided on the first layer and contains indium based oxide such as ITO, IZO, and IGZO. Therefore, by providing a second layer containing indium based oxide having a selection ratio which is small with respect to the etching liquid on the surface sides of the first touch electrode 21 and the second touch electrode 22, during a process of forming this opening 83a, the shapes of the first touch electrode 21 and the second touch electrode 22 can be retained, which is preferable.

Further, the first terminal 67 may also have two layer structure of a conductive material containing Al, Ag, Cu, Ni, Ti, Mo, or the like, and indium based oxide whose surface is hardly oxidized or so. In the case where the first terminal 67 contains indium based oxide on its surface side, when removing the first inorganic insulating film 71, the second inorganic insulating film 75, and the interlayer insulating film 83 by etching, due to the existence of the indium based oxide whose selection ratio with respect to the etching liquid is small, the shape of the first terminal 67 can be retained, which is preferable.

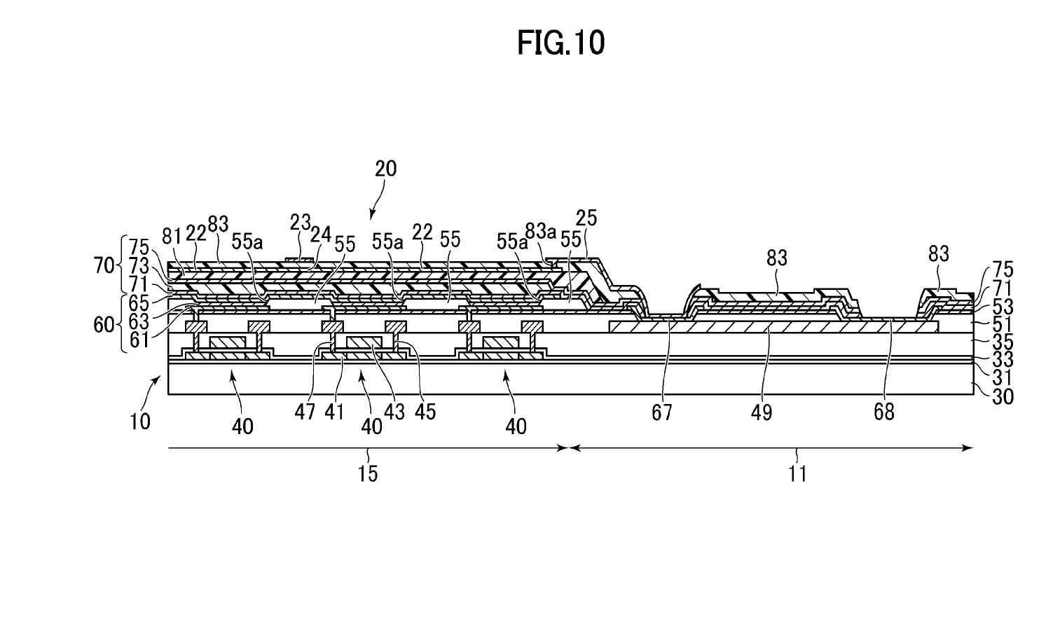

FIG. 10 illustrates a process to form the first connection line 23 and the leader wiring 25. The leader wiring 25 is connected to the first touch electrode 21 or the second touch electrode 22 via the opening 83a formed on the interlayer insulating film 83. Further, the leader wiring 25 is formed over the end faces of the first inorganic insulating film 71, the second inorganic insulating film 75, and the interlayer insulating film 83, and is formed to reach the upper surface of the first terminal 67 exposed by the etching process as described above. The first connection line 23 and the leader wiring 25 are formed by pattern formation including the photolithography process and the wet etching process.

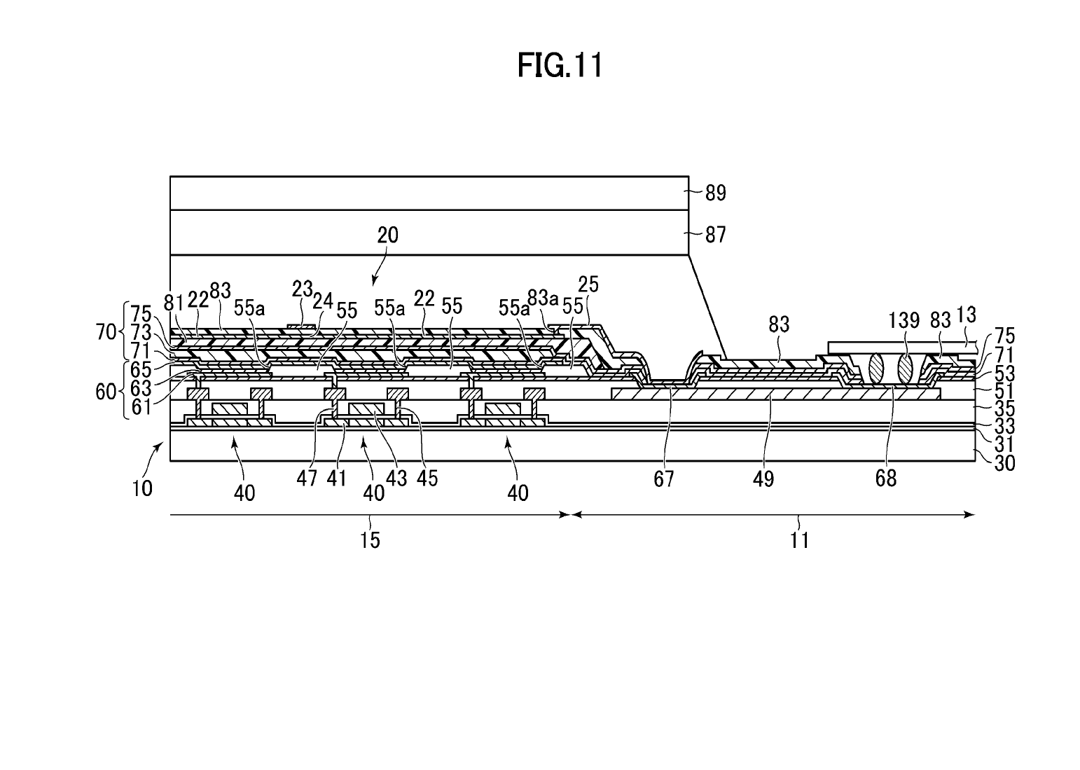

FIG. 11 illustrates a process to form a protective film 85 and the like which cover the touch sensor 20. Here, the protective film 85 is formed so as to cover all of the touch sensor 20, and additionally the leader wiring 25 and the first terminal 67. The protective film 85 is formed of an organic insulating material such as acrylic resin. On the protective film 85, a circular polarizing film 87 may be disposed. On the circular polarizing film 87, a cover film 89 may be disposed. Further, to the second terminal 68 which is not covered by the protective film 85, the FPC 13 is connected via the anisotropic conductive member 139.

As to the one or more embodiments as described above, the case where the touch sensor 20 is provided with the first touch electrode 21 and the second touch electrode 22 constituting the drive electrode and the detection electrode of the capacitive touch sensor is given as an example, but the touch sensor 20 may be further provided with an electrode for achieving a pressure sensing function in addition to those electrodes.

As to the present embodiment, as a disclosure example, an organic EL display device is given, but as another application example, any kind of flat panel display device such as a liquid crystal display device, another self-luminous display device, and an electric paper display device having electrophoretic elements or the like can be mentioned. Further, it is needless to say that the present invention can be applied to any size of display device, that is, small-medium to large, without any specific limitation.

It is understood that without departing from the spirit of the present invention, a person skilled in the art can arrive at various kinds of variations and modifications, and such variations and modifications fall within the scope of the present invention. For example, each of the one or more embodiments as described above to which addition, deletion, or design change of a component, or addition, omission, or condition change of a process is suitably applied by a person skilled in the art are also encompassed within the scope of the present invention as long as they do not depart from the spirit of the present invention.

What is claimed is:

1. A display device with a touch sensor comprising:
a substrate;
a first terminal which is on an upper surface side of the substrate;
a light emitting element which is on the upper surface side of the substrate;
a sealing film having a first inorganic insulating film, which covers the light emitting element;
a plurality of first touch electrodes which are arranged two dimensionally over the sealing film, two of the first touch electrodes that are adjacent to each other in a first direction being connected to each other via a first connection line;
a plurality of second touch electrodes which are arranged two dimensionally over the sealing film, two of the second touch electrodes that are adjacent to each other in a second direction which intersects the first direction being connected to each other via a second connection line which intersects the first connection line in a plan view;
an interlayer insulating film which is between the first connection line and the second connection line, and has an end face continuous to an end face of the first inorganic insulating film; and
a leader wiring which is over the end portion of the first inorganic insulating film and the end portion of the interlayer insulating film, and connects the first touch electrode or the second touch electrode to the first terminal.

2. The display device according to claim 1, wherein
an angle formed by the substrate and the end portion of the first inorganic insulating film is 40 degrees or less.

3. The display device according to claim 1, wherein
the sealing film further includes a second inorganic insulating film which is over the first inorganic insulating film, and
the second inorganic insulating film has an end portion which is continuous to the end portion of the first inorganic insulating film and the end portion of the interlayer insulating film.

4. The display device according to claim 1, wherein
at least one of the first touch electrode and the second touch electrode contain indium based oxide on their surface side.

5. The display device according to claim 1, wherein
at least one of the first touch electrode and the second touch electrode comprises:
a first layer containing a material to be in ohmic contact with an indium based material, and
a second layer being provided over the first layer and containing indium based oxide.

6. The display device according to claim 4, wherein
the indium based oxide contains at least one of ITO, IZO, and IGZO.

7. The display device according to claim 5, wherein
the indium based oxide contains at least one of ITO, IZO, and IGZO.

8. The display device according to claim 5, wherein
the material to be in ohmic contact with the indium based material contains Ag or MoW.

9. The display device according to claim 1, wherein
the leader wiring is electrically connected to a wiring which is under the light emitting element via the first terminal.

10. The display device according to claim 9, further comprising a second terminal at a position which is separated from the light emitting element more than the first terminal is, wherein
the wiring electrically connects the first terminal and the second terminal.

11. The display device according to claim 1, wherein
the end portion of the first inorganic insulating film and the end portion of the interlayer insulating film are arranged between the first terminal and the light emitting element in a plan view.

12. The display device according to claim 3, wherein
the end portion of the first inorganic insulating film, the end portion of the second inorganic insulating film, and the end portion of the interlayer insulating film are arranged between the first terminal and the light emitting element in a plan view.

13. The display device according to claim 1, wherein
the first terminal contains indium based oxide on its surface side.

14. A method for manufacturing a display device with a touch sensor, the method comprising steps of:
preparing a substrate which has a first terminal disposed on an upper surface side of the substrate;
forming a light emitting element which is on the upper surface side of the substrate;
forming a sealing film which includes a first inorganic insulating film covering the light emitting element and the first terminal;
forming a plurality of first touch electrodes which are arranged two dimensionally over the sealing film;
forming a plurality of second touch electrodes which are arranged two dimensionally over the sealing film;
forming a second connection line which connects two of the second touch electrodes that are adjacent to each other in a second direction which intersects a first direction;
forming an interlayer insulating film which covers the first touch electrodes, the second touch electrodes, the second connection line, and the first terminal;
forming a first connection line connecting two of the first touch electrodes that are adjacent to each other in the first direction over the interlayer insulating film, and intersecting the second connection line in a plan view;
exposing at least a part of the first terminal, and forming an end portion which is continuous to the first inorganic insulating film and the interlayer insulating film by etching the first inorganic insulating film and the interlayer insulating film on the first terminal; and
forming a leader wiring which is disposed over an end portion of the first inorganic insulating film and an end portion of the interlayer insulating film and connects the first touch electrode or the second touch electrode to the first terminal.

15. The method according to claim 14, wherein
in the etching the first inorganic insulating film and the interlayer insulating film on the first terminal, the interlayer insulating film on the first touch electrode or the second touch electrode is etched to expose at least a part of the first touch electrode or the second touch electrode.

16. The method according to claim 14, wherein
in the forming the leader wiring, the leader wiring is connected to at least a part of the first touch electrode or the second touch electrode which is exposed out of the interlayer insulating film.
